(19) United States
(12) Patent Application Publication
(10) Pub. No.: US 2005/0149809 A1
(43) Pub. Date: Jul. 7, 2005

(54) Real time determination of application problems, using a lightweight diagnostic tracer

(75) Inventors: David Robert Draeger, Rochester, MN (US); Hany A. Salem, Pflugerville, TX (US)

Correspondence Address: IBM CORPORATION;INTELLECTUAL PROPERTY LAW DEPT, 11400 BURNET ROAD, AUSTIN, TX, 78758, US

(73) Assignee: International Business Machines Corporation, Armonk, NY (US)

(21) Appl. No.: 10/732,626

(22) Filed: Dec. 10, 2003

(51) Int. Cl. G06F 11/00; H04L 1/00; G06F 11/30; H03M 13/00; G08C 25/00

(52) U.S. Cl. 714/746

(57) ABSTRACT

A solution provided here comprises monitoring one or more resources in a production environment, and in response to a triggering incident, outputting diagnostic data. The monitoring is performed within the production environment, and the diagnostic data is associated with the resources.

### COPYRIGHT NOTICE

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### FIELD OF THE INVENTION

The present invention relates generally to information handling, and more particularly to error handling, recovery, and problem solving, for software and information-handling systems.

### BACKGROUND OF THE INVENTION

Sometimes users introduce error-prone applications, into a production environment where top performance is important. Appropriate problem-solving tools are then needed. Conventional problem-solving for applications often involves prolonged data-gathering and debugging. Collection of diagnostic data, if done in conventional ways, may impact performance in unacceptable ways.

Various approaches have been proposed for handling errors or failures in computers. In some examples, error-handling is not separated from hardware. In other examples, automated gathering of useful diagnostic information is not addressed. Other solutions require network connectivity to production servers to provide monitoring of a production environment. This introduces security concerns and concerns about network bandwidth usage. Other solutions use heavyweight tracing mechanisms that introduce excess overhead, due to the monitoring of more components than necessary.

Thus there is a need for systems and methods that automatically collect useful diagnostic information in a production environment, while avoiding unacceptable impacts on security and performance.

### SUMMARY OF THE INVENTION

A solution to problems mentioned above comprises monitoring one or more resources in a production environment, and in response to a triggering incident, outputting diagnostic data. The monitoring is performed within the production environment, and the diagnostic data is associated with the resources.

### BRIEF DESCRIPTION OF THE DRAWINGS

A better understanding of the present invention can be obtained when the following detailed description is considered in conjunction with the following drawings. The use of the same reference symbols in different drawings indicates similar or identical items.

FIG. 1 illustrates a simplified example of a computer system capable of performing the present invention.

FIG. 2 is a block diagram illustrating an example of method and system of handling errors, according to the teachings of the present invention.

FIG. 3 is a block diagram illustrating another example of a method and system of handling errors, involving a connection pool.

FIG. 4 is a flow chart, illustrating an example of a method of handling errors.

### DETAILED DESCRIPTION

The examples that follow involve the use of one or more computers, and may involve the use of one or more communications networks, or the use of various devices, such as embedded systems. The present invention is not limited as to the type of computer or other device on which it runs, and not limited as to the type of network used. The invention could be implemented for handling errors in any kind of component, device or software.

The following are definitions of terms used in the description of the present invention and in the claims:

“Computer-usable medium” means any carrier wave, signal or transmission facility for communication with computers, and any kind of computer memory, such as floppy disks, hard disks, Random Access Memory (RAM), Read Only Memory (ROM), CD-ROM, flash ROM, non-volatile ROM, and non-volatile memory.

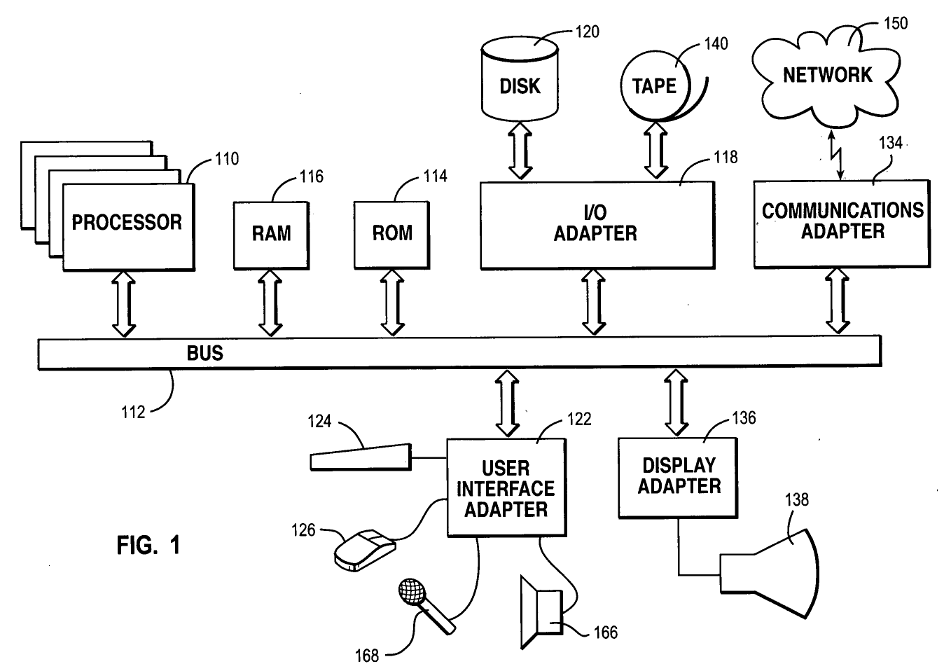

FIG. 1 illustrates a simplified example of an information handling system that may be used to practice the present inventon. The invention may be implemented on a variety of hardware platforms, including embedded systems, personal computers, workstations, servers, and mainframes. The computer system of FIG. 1 has at least one processor 110. Processor 110 is interconnected via system bus 112 to random access memory (RAM) 116, read only memory (ROM) 114, and input/output (I/O) adapter 118 for connecting peripheral devices such as disk unit 120 and tape drive 140 to bus 112. The system has user interface adapter 122 for connecting keyboard 124, mouse 126, or other user interface devices such as audio output device 166 and audio input device 168 to bus 112. The system has communication adapter 134 for connecting the information handling system to a communications network 150, and display adapter 136 for connecting bus 112 to display device 138. Communication adapter 134 may link the system depicted in FIG. 1 with hundreds or even thousands of similar systems, or other devices, such as remote printers, remote servers, or remote storage units. The system depicted in FIG. 1 may be linked to both local area networks (sometimes referred to as intranets) and wide area networks, such as the Internet.

While the computer system described in FIG. 1 is capable of executing the processes described herein, this computer system is simply one example of a computer system. Those skilled in the art will appreciate that many other computer system designs are capable of performing the processes described herein.

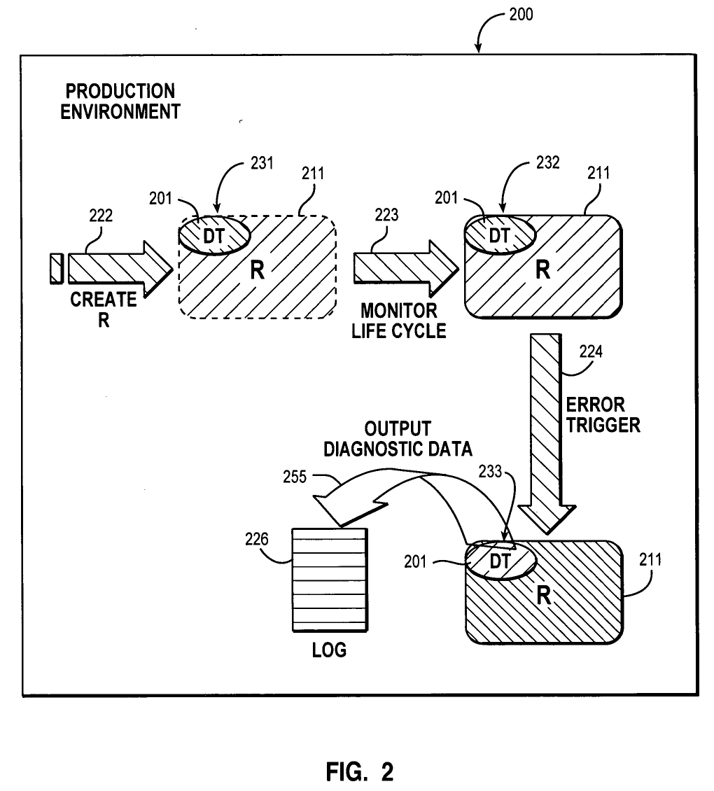

FIG. 2 is a block diagram illustrating an example of method and system of handling errors. Beginning with an overview, inside production environment 200, a diagnostic tracer (DT, block 201) is associated with a resource (R, block 211). Three positions 231, 232, and 233, symbolize three points in the life cycle of resource 211. This diagram may apply to various scenarios. Resource 211 could be a connection, a thread, or other object of interest, like a graphical user interface (GUI), for example.

Some basic operations are shown in FIG. 2. Arrow 222 symbolizes creating a resource 211 in a production environment 200. This involves creating a lightweight diagnostic tracer 201 and embedding the tracer 201 in the resource 211.

Arrow 223 symbolizes monitoring resource 211 throughout its life cycle. At position 233, in response to a triggering incident or error (arrow 224), there is outputting of diagnostic data (arrow 255) to log 226. Diagnostic data is extracted (arrow 255) from the diagnostic tracer 201 that is embedded in the resource 211. Diagnostic data in log 226 may be used for problem-solving by local personnel, by remote personnel, or by an automated problem-solving process.

Some prior art solutions require network connectivity to the production servers to provide monitoring or analysis of the production environment. This introduces security concerns and concerns about network bandwidth usage. However, in the example in FIG. 2, monitoring is performed within the production environment (arrow 223 and diagnostic tracer 201 are shown inside production environment 200).

Some prior art solutions use heavyweight tracing mechanisms that introduce excess overhead, due to the monitoring of more components than necessary. However, in the example in FIG. 2, diagnostic data 255 is associated with resource 211, which is an object of interest for problem-solving. There is almost always a performance impact when using some prior art tracing mechanisms. However, in the example in FIG. 2, there is outputting of diagnostic data (arrow 255) in response to a triggering incident (arrow 224), involving a performance impact only at necessary times. These are ways of minimizing overhead associated with monitoring and outputting. Minimal overhead is symbolized by the relatively small size of diagnostic tracer 201.

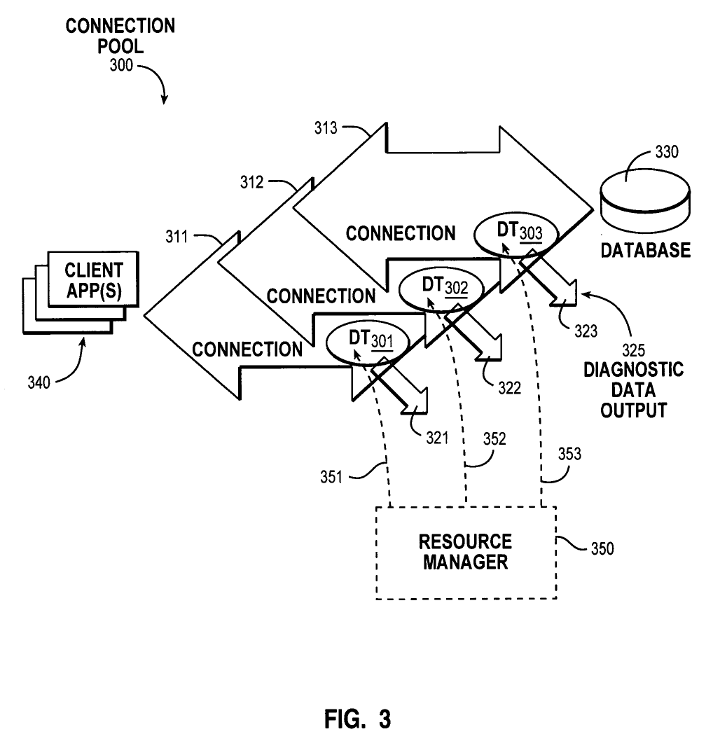

FIG. 3 is a block diagram illustrating another example of method and system of handling errors, involving a connection pool. Connection pool 300 provides connections between one or more client applications 340 and database 330. A client application at 340 gets a connection (one of the connections numbered 311-313), to perform an operation involving database 330. Connection pool 300 may be implemented as a pool of objects. This example involves monitoring a number of resources (connections 311-313) in a production environment that includes pool 300, client applications at 340 and database 330. Customers may introduce into the production environment at 340 some applications that generate errors. In response to a triggering incident, there is outputting (at 325) of diagnostic data, symbolized by the set of arrows 321-323. The monitoring is performed by the diagnostic tracers 301-303 within the production environment. The diagnostic data (arrows 321-323) is associated with a number of resources (connections 311-313). Diagnostic data is extracted (at 325) from the diagnostic tracers 301-303 embedded in connections 311-313. Based on the diagnostic data, troubleshooting may identify an opportunity to improve the performance of an application.

Block 350, with broken lines, symbolizes an optional resource manager. This example in FIG. 3 includes some possible roles for resource manager 350, such as measuring a condition, comparing the condition to a threshold value (such as a timeout value), and triggering (arrows 351-353) output of diagnostic data (arrows 321-323) from one or more resources (connections 311-313), when the measured condition equals or exceeds the threshold value. A resource manager 350 of a pre-existing software product provides a mechanism for adding diagnostic tracers to that software product (e.g. adding diagnostics to a connection manager).

Resource manager 350 provides a mechanism for activating and configuring (arrows 351-353) diagnostic tracers 301-303, for troubleshooting connection-related issues. Users may encounter connection management issues that are related to application code or configuration problems. For example, these issues may include “orphaned” database connections. If an application at 340 does not properly close connections after use, the connection may not be returned to the connection pool 300 for reuse in the normal manner. After a given time limit, the resource manager 350 may forcibly return the orphaned connections to the pool 300. However, this code pattern often results in slow performance or timeout exceptions because no connections are available for reuse. If a request for a new connection is not fulfilled in a given amount of time, due to all connections in the pool 300 being in use, then a timeout exception is returned to the application at 340. An assessment of why connections are being improperly held must be performed. Diagnostic tracers 301-303 serve as means for monitoring connections 311-313 and means for outputting diagnostic data (arrows 321-323). Configuring (arrows 351-353) diagnostic tracers 301-303, for troubleshooting connection-related issues, may comprise specifying at least one triggering incident of interest, and specifying at least one type of desired diagnostic data. A configuration for diagnostic tracers 301-303 may utilize one or more types of triggering incident, such as exceeding a timeout value, throwing an exception, and forcibly returning a connection to pool 300.

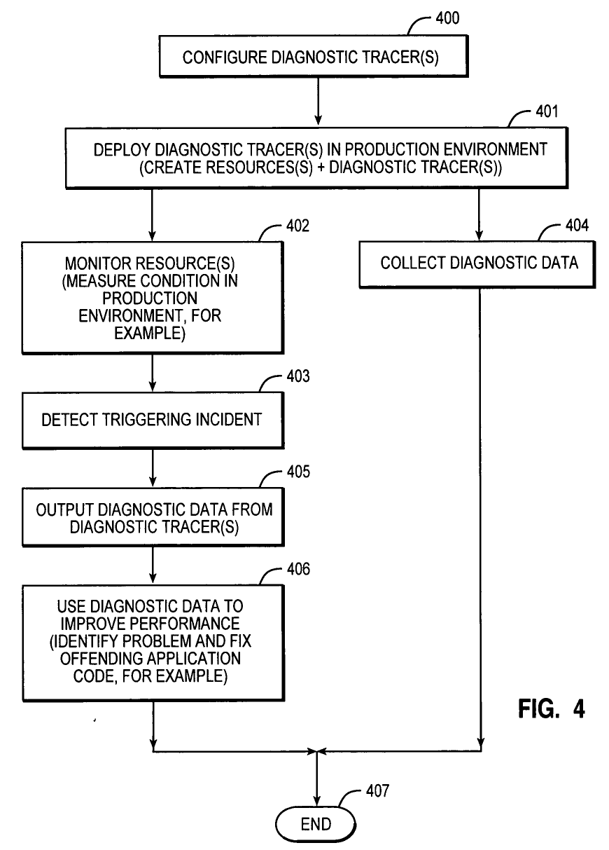

FIG. 4 is a flow chart, illustrating an example of a method of handling errors. The flow chart may apply to various scenarios for using diagnostic tracers. This example begins at block 400, configuring a diagnostic tracer. This involves providing multiple diagnostic options, concerning the triggering incident, or the outputting diagnostic data, or both.

Next, block 401 represents activating or deploying the diagnostic tracer, when diagnostic data is needed for problem-solving (creation of one or more resources with diagnostic tracers). The diagnostic tracer contains information used to identify the resource.

In this example, collecting diagnostic data starts at block 404, in parallel with monitoring one or more resources, block 402. The data-collection process may begin at any point (e.g., create the object to be monitored and populate the diagnostic tracer with the diagnostic data immediately, or at a later time). We provide the capability to add diagnostic information throughout a monitored resource's life cycle, so that a complete “breadcrumb” trail could be displayed as the diagnostic data if necessary. In response to a triggering incident detected at block 403, diagnostic data output occurs at block 405.

In this example in FIG. 4, collecting diagnostic data (404) continues through block 406, using diagnostic data to improve the performance of an application. Even when the existing diagnostic data is dumped (405), tracers can still be collecting data (404), to make sure a complete set of data is always gathered. Block 407 symbolizes the end of one round of problem-solving.

Turning to some details of FIG. 4, configuring diagnostic tracers (block 400) may involve multiple diagnostic options. There may be options provided for outputting one or more types of diagnostic data, such as an informational message, a timestamp designating the time of the incident, a stack trace associated with an offending resource, and stack traces associated with a plurality of resources. There may be options provided for utilizing one or more types of triggering incident, such as exceeding a timeout value, throwing an exception, and forcibly returning a connection to a pool. Other diagnostic options are possible. Diagnostic options are not limited to the examples provided here.

Concerning creation of one or more resources with diagnostic tracers, (block 401) consider some examples of how to create a diagnostic tracer. The following is pseudo code that shows two possible ways the tracer could be embedded into a resource when it is either created or requested:

Example 1—Initialize Tracer in Constructor of Monitored Resource:

// The MyResource Class
public class MyResource( ) {

DiagnosticTracer tracer = null; // The monitored

// resource embeds the tracer object

// When the monitored resource is initialized, it

// initializes the diagnostic tracer

public void MyResource( ) {

this.tracer = new DiagnosticTracer( ); // A new

// diagnostic tracer is created in the resource
// constructor.

}

}

Example 2—Initialize Tracer when Resource is about to be Used by Customer Application Code

. . .
// Customer code has requested a resource
// Initialize the tracer and hand the new object (with
// a tracer) to the customer code
if
(MyResourceManager.diagnosticMonitoringEnable
d( )) { // Check if a
// tracer needs to be added to the resource

DiagnosticTracer tracer = new

DiagnosticTracer( ); // Create a new tracer
// to embed in the resource

MonitoredResource resource = new

MonitoredResource( ); // Create the
// new monitored resource to be given to the
// customer code

resource.setTracer(tracer); // Embed

// the tracer into the monitored resource

return resource; // Give the

// resource with the tracer to the customer code
}

Continuing with details of FIG. 4, consider output of diagnostic data (block 405). For troubleshooting connection-related problems (as described above regarding FIG. 3), one might utilize diagnostic data like the following examples:

Example Diagnostic Output—Orphaned Connection Notification—when a connection is forcibly returned to the connection pool, a short message is written to a log file (StdOut.log):
[6/10/03 13:19:27:644 CDT] 7c60c017 ConnectO W CONM6027W: A

Connection has been Orphaned and returned to pool Sample DataSource. For information about what code path is orphaning connections, set the datasource property “diagoptions” to 2 on the datasource “Sample DataSource”.

Example Diagnostic Output—Orphaned Connection Application Code Path Tracing—a stack trace snapshot is taken when the getConnection request is fulfilled. This will allow customers to analyze which pieces of their code are not correctly returning connections. When a connection is forcibly returned to the connection pool, a stack trace is written to a log file (StdOut.log):
Orphaned Connection Detected at: Wed May 7 13:33:56 CDT 2003

Use the following stack trace to determine the problematic code path. java.lang.Throwable: Orphaned Connection Tracer
at com.ibm.ejs.cm.pool.ConnectO.setTracer(ConnectO.java:3222)

at

com.ibm.ejs.cm.pool.ConnectionPool.findFreeConnection(ConnectionPool.java:998
)
at
com.ibm.ejs.cm.pool.ConnectionPool.findConnectionForTx(ConnectionPool.java:85
8)
at
com.ibm.ejs.cm.pool.ConnectionPool.allocateConnection(ConnectionPool.java:792)
at com.ibm.ejs.cm.pool.ConnectionPool.getConnection(ConnectionPool.java:369)
at com.ibm.ejs.cm.DataSourcelmpl$1.run(DataSourcelmpl.java:135)
at java.security.AccessController.doPrivileged(Native Method)
at com.ibm.ejs.cm.DataSourcelmpl.getConnection(DataSourcelmpl.java:133)
at com.ibm.ejs.cm.DataSourcelmpl.getConnection(DataSourcelmpl.java:102)
at cm.ThrowableTest.runTestCode(ThrowableTest.java:54)
at cm.ThrowableTest.doGet(ThrowableTest.java:177)
at javax.servlet.http.HttpServlet.service(HttpServlet.java:740)
. . .

Example Diagnostic Output—Connection Wait Timeout Code Path Tracing—a third diagnostic option prints the getConnection stack trace snapshots for each connection in use when a ConnectionWaitTimeoutException is thrown. This will allow customers to analyze which pieces of code are holding connections at the time of the exception. This may indicate connections being held longer than necessary, or being orphaned. It may also indicate normal usage, in which case the customer should increase the size of their connection pool, or their Connection wait timeout. A stack trace is written to a log file (StdOut.log):
[6/10/03 15:37:17:748 CDT] 7e4c1051 ConnectionPoo W CONM6026W: Timed out waiting for a connection from data source Sample DataSource. Connection Manager Diagnostic Tracer-Connection creation time: Tue Jun 10 15:36:46 CDT 2003
at com.ibm.ejs.cm.pool.ConnectO.setTracer(ConnectO.java:3649)
at
com.ibm.ejs.cm.pool.ConnectionPool.findFreeConnection(ConnectionPool.java:100 4)
at
com.ibm.ejs.cm.pool.ConnectionPool.findConnectionForTx(ConnectionPool.java:85 7)
at
com.ibm.ejs.cm.pool.ConnectionPool.allocateConnection(ConnectionPool.java:790)
at com.ibm.ejs.cm.pool.ConnectionPool.getConnection(ConnectionPool.java:360)
at com.ibm.ejs.cm.DataSourcelm pl$1.run(DataSourceImpl.java:151)
at java.security.AccessController.doPrivileged(Native Method)
at com.ibm.ejs.cm.DataSourceImpl.getConnection(DataSourceImpl.java:149)
at com.ibm.ejs.cm.DataSourceImpl.getConnection(DataSourcelmpl.java:118)
at cm.ThrowableTest.runTestCode(ThrowableTest.java:54)
at cm.ThrowableTest.doGet(ThrowableTest.java:177)
at javax.servlet.http.HttpServlet.service(HttpServlet.java:740)

These examples of diagnostic data output (FIG. 4, block 405) allow troubleshooting (block 406) of connection related issues that are related to application code or configuration problems.

Continuing with details of FIG. 4, consider some other examples of identifying an opportunity to improve the performance of an application, based on diagnostic data (block 406). The diagnostic data can be used to quickly identify the misbehaving component within the application that caused the malfunction. For example, the diagnostic tracer data may be a JAVA call stack which can be used to easily identify the calling method of the application that is causing the inappropriate behavior. An example is allowing a resource manager dump the diagnostic information (call stacks) from all of the diagnostic tracers, whenever a certain threshold is reached. This allows quick identification of the resource “hog” when resources are exhausted. Another example is allowing the resource manager to trigger only the diagnostic tracer of the offending resource after a certain threshold is reached. This provides unique information about the state of the offending resource that caused it to break the threshold barrier. The system may be adjusted appropriately to prevent this state from occurring again. Finally, the diagnostic tracer may monitor its own environment, and have a self triggering mechanism dump the diagnostic information when the environment crosses some threshold, or changes from a steady state.

Another example of output and use of diagnostic data (FIG. 4, blocks 405-406) involves a diagnostic tracer associated with a graphical user interface. The diagnostic tracer may capture diagnostic data concerning windows that a user travels through. The output may be a list of identifiers for buttons that a user clicks on. The diagnostic data output allows troubleshooting to improve the performance of the graphical user interface and associated applications.

Regarding FIG. 4, the order of the operations described above may be varied. For example, it is within the practice of the invention for the data-collection process (404) to begin at any point. Blocks in FIG. 4 could be arranged in a somewhat different order, but still describe the invention. Blocks could be added to the above-mentioned diagram to describe details, or optional features; some blocks could be subtracted to show a simplified example.

This final portion of the detailed description presents a few details of a working example implementation. Lightweight diagnostic tracers were implemented for handling errors in web application server software (the software product sold under the trademark WEBSP HERE by IBM). The WEBSPHERE Connection Manager provided diagnostics, allowing customers to gather information on what pieces of their applications were orphaning connections, or holding them for longer than expected. This implementation used object-oriented programming, with the JAVA programming language. The diagnostic tracer was a throwable object. The performance impact of turning on the diagnostic options ranged from 1%-5% performance degradation, depending on which options were activated and how many were activated. This example implementation was the basis for the simplified example illustrated in FIG. 3.

In conclusion, we have shown solutions that monitor one or more resources in a production environment, and in response to a triggering incident, output diagnostic data.

One of the possible implementations of the invention is an application, namely a set of instructions (program code) executed by a processor of a computer from a computer-usable medium such as a memory of a computer. Until required by the computer, the set of instructions may be stored in another computer memory, for example, in a hard disk drive, or in a removable memory such as an optical disk (for eventual use in a CD ROM) or floppy disk (for eventual use in a floppy disk drive), or downloaded via the Internet or other computer network. Thus, the present invention may be implemented as a computer-usable medium having computer-executable instructions for use in a computer. In addition, although the various methods described are conveniently implemented in a general-purpose computer selectively activated or reconfigured by software, one of ordinary skill in the art would also recognize that such methods may be carried out in hardware, in firmware, or in more specialized apparatus constructed to perform the method.

While the invention has been shown and described with reference to particular embodiments thereof, it will be understood by those skilled in the art that the foregoing and other changes in form and detail may be made therein without departing from the spirit and scope of the invention. The appended claims are to encompass within their scope all such changes and modifications as are within the true spirit and scope of this invention. Furthermore, it is to be understood that the invention is solely defined by the appended claims. It will be understood by those with skill in the art that if a specific number of an introduced claim element is intended, such intent will be explicitly recited in the claim, and in the absence of such recitation no such limitation is present. For non-limiting example, as an aid to understanding, the appended claims may contain the introductory phrases “at least one” or “one or more” to introduce claim elements. However, the use of such phrases should not be construed to imply that the introduction of a claim element by indefinite articles such as “a” or “an” limits any particular claim containing such introduced claim element to inventions containing only one such element, even when the same claim includes the introductory phrases “at least one” or “one or more” and indefinite articles such as “a” or “an;” the same holds true for the use in the claims of definite articles.

1. A method of handling errors in a computer system, said method comprising:
monitoring at least one resource in a production environment; and
in response to a triggering incident, outputting diagnostic data;
wherein:
said monitoring is performed within said production environment; and
said diagnostic data is associated with said at least one resource.

2. The method of claim 1, wherein said monitoring further comprises:
measuring a condition; and
comparing said condition to a threshold value;
wherein said triggering incident occurs when said measured condition equals or exceeds said threshold value.

3. The method of claim 1, further comprising:
minimizing overhead associated with said monitoring and said outputting; and
monitoring said resource throughout its life cycle.

4. The method of claim 1, wherein said outputting further comprises outputting diagnostic data associated with a plurality of resources.

5. The method of claim 1, wherein said outputting further comprises outputting diagnostic data associated with an offending resource.

6. The method of claim 1, wherein said outputting further comprises outputting an identifier for said resource.

7. The method of claim 1, further comprising:
configuring a diagnostic tracer to respond to at least one triggering incident of interest; and
activating said diagnostic tracer, when said diagnostic data is needed.

8. The method of claim 1, further comprising:
providing multiple diagnostic options, concerning:
said triggering incident,
or said outputting diagnostic data,
or both.

9. The method of claim 1, wherein said outputting further comprises outputting one or more types of diagnostic data selected from the group consisting of
an informational message,
a timestamp designating the time of said, triggering incident,
a stack trace associated with an offending resource,
and stack traces associated with a plurality of resources.

10. The method of claim 1, further comprising utilizing one or more types of triggering incident selected from the group consisting of
exceeding a timeout value,
throwing an exception,
and forcibly returning a connection to a pool.

11. A method of handling errors in a computer system, said method comprising:
creating a resource in a production environment;
monitoring said resource throughout its life cycle;
in response to a triggering incident, outputting diagnostic data; and
minimizing overhead associated with said monitoring and said outputting;
wherein:
said monitoring is performed within said production environment;
said monitoring is selectively performed when said diagnostic data is needed; and
said diagnostic data is associated with said resource.

12. The method of claim 11, wherein said creating further comprises:
creating a lightweight diagnostic tracer; and
embedding said tracer in said resource.

13. The method of claim 11, further comprising:
providing multiple diagnostic options, concerning:
said triggering incident,
or said outputting diagnostic data,
or both.

14. The method of claim 11, wherein said outputting further comprises outputting one or more types of diagnostic data selected from the group consisting of
an informational message,
a timestamp designating the time of said triggering incident,
a stack trace associated with an offending resource,
and stack traces associated with a plurality of resources.

15. The method of claim 11, further comprising utilizing one or more types of triggering incident selected from the group consisting of
exceeding a timeout value,
throwing an exception,
and forcibly returning a connection to a pool.

16. The method of claim 11, further comprising:
identifying an opportunity to improve the performance of an application, based on said diagnostic data.

17. A system of handling errors in a computer system, said system comprising:
means for monitoring at least one resource in a production environment; and
means responsive to a triggering incident, for outputting said diagnostic data;
wherein:
said means for monitoring operates within said production environment; and
said diagnostic data is associated with said at least one resource.

18. The system of claim 17, wherein said means for monitoring further comprises:
means for measuring a condition; and
means for comparing said condition to a threshold value;
wherein said triggering incident occurs when said measured condition equals or exceeds said threshold value.

19. The system of claim 17, wherein:
said means for outputting is lightweight; and
said means for outputting is associated with said resource throughout the life cycle of said resource.

20. The system of claim 17, wherein said means for monitoring is a throwable object.

21. The system of claim 17, wherein said means for outputting further comprises means for outputting diagnostic data associated with a plurality of resources.

22. The system of claim 17, wherein said means for outputting further comprises means for selectively outputting diagnostic data associated with an offending resource.

23. The system of claim 17, wherein:
said means for monitoring may be configured to specify at least one triggering incident of interest; and
said means for outputting may be configured to specify at least one type of diagnostic data.

24. A computer-usable medium, having computer-executable instructions for handling errors in a computer system, said computer-usable medium comprising:
means for monitoring at least one resource in a production environment; and
means responsive to a triggering incident, for outputting said diagnostic data;
wherein:
said means for monitoring operates within said production environment; and
said diagnostic data is associated with said at least one resource.

25. The computer-usable medium of claim 24, wherein said means for monitoring further comprises:
means for measuring a condition; and
means for comparing said condition to a threshold value;
wherein said triggering incident occurs when said measured condition equals or exceeds said threshold value.

26. The computer-usable medium of claim 24, wherein:
said means for outputting is lightweight; and
said means for outputting is associated with said resource throughout the life cycle of said resource.

27. The computer-usable medium of claim 24, wherein said means for monitoring is a throwable object.

28. The computer-usable medium of claim 24, wherein said means for outputting further comprises means for outputting diagnostic data associated with a plurality of resources.

29. The computer-usable medium of claim 24, wherein said means for outputting further comprises means for selectively outputting diagnostic data associated with an offending resource.

30. The computer-usable medium of claim 24, wherein:
said means for monitoring may be configured to specify at least one triggering incident of interest; and
said means for outputting may be configured to specify at least one type of diagnostic data
